(19) United States
(12) Patent Application Publication
(10) Pub. No.: US 2026/0146361 A1
(43) Pub. Date: May 28, 2026

(54) PRODUCTION OF SILICON CARBIDE EPITAXIAL WAFERS

(71) Applicant: KISELKARBID I STOCKHOLM AB, Kista (SE)

(72) Inventor: Johan EKMAN, Saltsjöbaden (SE)

(73) Assignee: KISELKARBID I STOCKHOLM AB, Kista (SE)

(21) Appl. No.: 19/121,730

(22) PCT Filed: Aug. 15, 2023
(86) PCT No.: PCT/SE2023/050824

§ 371 Date: Apr. 16, 2025

(30) Foreign Application Priority Data
Nov. 28, 2022 (SE) 2251383-2

(51) Int. Cl. C30B 23/02; C30B 29/36; H10D 62/832

(52) U.S. Cl. CPC C30B 23/025; C30B 29/36; H10D 62/8325

(57) ABSTRACT

A method for producing silicon carbide, SiC, epitaxial wafers in a wafer growth system (1) comprising an outer container, an insulating container arranged inside the outer container, a growth container (2) arranged inside the insulating container, and a heating arrangement arranged outside the outer container to heat an inside of the growth container (2). The method comprises providing a source material (3) of polycrystalline SiC in the growth container (2), providing a substrate (4) of monocrystalline SiC in the growth container (2) substantially parallel to the source material (3), the substrate (4) having a doping concentration of ≤5—10¹⁶ cm⁻³, increasing the temperature in the growth container (2) to a sublimation temperature of the source material (3), maintaining the temperature in the growth container (2) until a conductive layer (6) of monocrystalline SiC having a thickness of ≥10 μm and having a doping concentration of ≥1·10¹⁸ cm⁻³ has grown on the substrate (4). The substrate (4) and the grown conductive layer (6) together define an epitaxial boule. The method further comprises cooling the epitaxial boule to room temperature, and slicing the epitaxial boule, through the substrate (4) in a plane substantially parallel to the grown conductive layer (6), into an excess substrate (8) and an epitaxial wafer comprising a substrate layer (7) having the grown conductive layer (6) thereon.

### TECHNICAL FIELD

The present invention relates generally to production of silicon carbide epitaxial wafers.

### BACKGROUND ART

Semiconductor materials and devices can be found in all kinds of electronic devices. One application is in power semiconductor devices, or power devices. Power devices have the function of converting and/or controlling electrical energy between the energy source and the energy consumer. Power devices can be found in power grids, power supplies for computers, power management in smart phones, and automotive electronics, to name a few.

Silicon carbide (SiC) is a next generation semiconductor material which is gaining interest in the power device industry. Using SiC enables more energy efficient power devices with lower cooling needs and higher system integration densities. However, there is still a need for technical solutions relating to the production of SiC semiconductor material.

SiC epitaxial wafers are thin semiconductor discs generally formed by two main layers, one with high doping concentration and one with low doping concentration. The layer with high doping concentration is commonly known as the conductive layer. The layer with low doping concentration is commonly known as the drift layer.

The quality of the drift layer is crucial to the quality of the final product. The quality of the drift layer is defined by the defect density. Typical defects in the drift layer are down falls (carbon particles), carrot defects, triangular stacking faults, basal plane dislocations (BPD), bar-type stacking faults, threading screw dislocations and threading edge dislocations.

In prior art, SiC epitaxial wafers are produced by depositing the drift layer on the conductive layer. More specifically, conductive substrates with high doping concentration (conductive layer) are produced in physical vapor transport (PVT) furnaces and successively, after crystal slicing, grinding and polishing, a layer of low doping concentration (drift layer) is deposited by means of chemical vapor deposition (CVD) on the substrate.

The quality of the drift layer being deposited on the conductive substrate is determined by the level of process control, but also by the crystalline quality of the conductive substrate. This is because defects in the conductive substrate propagate to the drift layer during growth thereof. Therefore, the quality of the conductive substrate will be a limiting factor in the effort of producing high quality epitaxial wafers. Today, it is not considered possible to achieve a completely defect free drift layer using existing technology.

Another problem with prior art processes is related to stress in the drift layer. When the drift layer is grown on the conductive layer, stress is built up in the drift layer. This is for example caused by the drift layer having a smaller volume compared to the conductive layer. The difference in volume is caused by the doping, wherein the type of dopant atoms (and their respective radii) and the doping concentration causes the crystal lattice to expand or contract. The stress in the drift layer may appear during growth, but may also appear during post growth cooling and cause crystal planes to glide and thereby formation of for example stacking faults.

Another parameter affecting the quality of epitaxial wafers today is the doping homogeneity, where problems are related to the conductive layer as well as the drift layer. Today, doping homogeneity of conductive layers are commonly around 20%, meaning that the doping concentration difference between the areas in the material with the highest and lowest doping concentration is 20%. A doping homogeneity on this level for example leads to varying resistivity in the material, which in turn has a negative impact on the yield (usable area of the wafer). It furthermore negatively affects temperature distribution in the material. Furthermore, during growth (when the doping takes place), inhomogeneous doping may affect the growth properties leading to less uniform growth surfaces, which naturally also affects the yield.

Thus, there is a need for technical solutions for the production of SiC epitaxial wafers, in order to further decrease the defect density in SiC epitaxial wafers.

### DEFINITIONS

Doping: Doping is the process of increasing the number of charge carriers in the crystal structure. The net doping concentration is defined as the difference between the number (Na) of electron donors and the number (Na) of electron acceptors. Nitrogen atoms are common electron donors. Boron and aluminum atoms are common electron acceptors. The net doping concentration can be measured in different manners, for example: the concentration of doping atoms may be measured through secondary ion mass spectroscopy (SIMS), the concentration of ionized doping atoms may be measured through capacitance voltage (CV) measurement, the concentration of charge carriers may be measured through Hall measurement.

N-type doping: Doping with atoms that may supply negative charge carriers, electrons, to the crystal structure. A common n-type dopant is nitrogen. Doping is commonly performed by introduction of a dopant gas during material growth, such as nitrogen gas. The resulting doping type (n-type or p-type) of the material is determined by the most abundant p-or n-type electrically active atoms.

P-type doping: Doping with atoms that may supply positive charge carriers, known as holes. Aluminum is a common p-type dopant, and doping is then commonly performed by introduction of a dopant gas, such as trimethylaluminium (TMA) gas or use of a source material comprising aluminum, or alternatively introduction of a powder such as aluminum carbide powder (Al₄C₃). Boron is another common p-type dopant. The resulting doping type (n-type or p-type) of the material is determined by the most abundant p-or n-type electrically active atoms.

Epitaxial wafer: A monocrystalline SiC wafer comprising a conductive layer of SiC with a high doping concentration and a drift layer of SiC with a low doping concentration. A high doping concentration should herein be understood as ≥1·10¹⁸ cm⁻³. A low doping concentration should herein be understood as ≤5·10¹⁶ cm⁻³, preferably ≤1·10¹⁶ cm⁻³.

### SUMMARY OF INVENTION

An object of the present invention is to overcome at least some of the problems outlined above.

In a first aspect of the disclosure this is achieved by providing a method for producing silicon carbide, SiC, epitaxial wafers in a wafer growth system comprising an outer container, an insulating container arranged inside the outer container, a growth container arranged inside the insulating container, and a heating arrangement arranged outside the outer container to heat an inside of the growth container. The method comprises providing a source material of polycrystalline SiC in the growth container, providing a substrate of monocrystalline SiC in the growth container substantially parallel to the source material, the substrate having a doping concentration of ≤5·10¹⁶ cm⁻³, increasing the temperature in the growth container to a sublimation temperature of the source material, maintaining the temperature in the growth container until a conductive layer of monocrystalline SiC having a thickness of ≥10 μm and having a doping concentration of ≥1·10¹⁸ cm⁻³ has grown on the substrate, wherein the substrate and the grown conductive layer together define an epitaxial boule, cooling the epitaxial boule to room temperature, and slicing the epitaxial boule, through the substrate in a plane substantially parallel to the grown conductive layer, into an excess substrate and an epitaxial wafer comprising a substrate layer having the grown conductive layer thereon.

By this novel method, high quality epitaxial wafers can be produced which will contribute to increase device performance, such as lower electrical loss due to lower resistance, and increased reliability, such as lower risk for bipolar degradation. By providing a high quality, low-doped substrate, it is possible to completely avoid growing low-doped material on high-doped material during manufacture of epitaxial wafers. One advantage of this is that the quality of the low-doped material (drift layer) is no longer limited by the quality of the conductive layer. That is, defects present in the conductive layer cannot propagate to the drift layer.

One other advantage is the absence of stresses which, in prior art, are translated from the high-doped material to the low-doped material. With the claimed method, such translated stresses are no longer a limiting quality factor for the low-doped material (drift layer).

Another advantage is an improved device yield. The device yield relates to the percentage of working components on a wafer. Due to the improved quality achieved with the claimed method and the decrease in defects formed during epitaxial growth, the device yield is improved.

Another advantage of growing the conductive layer on the low-doped substrate is the improved doping homogeneity of the conductive layer. The improved doping homogeneity provides a more uniform temperature distribution, more uniform growth properties, more uniform resistivity, and improved yield.

Another advantage of growing the conductive layer on the low-doped substrate is that requirements on surface preparation of the substrate are less strict, compared to prior art, since the defect density requirements in the conductive layer are less stringent than those in the drift layer. Defects caused by surface preparation imperfections such as scratches or etching pits may be allowable in the conductive layer, whereas the same defects in the drift layer would render it unusable.

The novel method is at least made possible by applying a sublimation growth process which provides a high level of process control and control of the crystalline growth, and thereby control of the crystalline quality. In prior art processes, where the drift layer is grown on the conductive layer, a sublimation growth process is not applicable because at sublimation temperatures of SiC the dopants in the conductive layer would be released into the vapor phase and, by diffusion, poison the drift layer growing thereon.

In some examples, the substrate has a doping concentration of ≤1·10¹⁶ cm⁻³.

In some examples, the substrate, and thus the substrate layer of the epitaxial wafer, is of n-type doping.

In some examples, the substrate, and thus the substrate layer of the epitaxial wafer, is of p-type doping.

In some examples, the substrate has a thickness of ≥100 μm.

In some examples, the substrate is substantially free from basal plane dislocations.

In some examples, the substrate is substantially free from stacking faults.

In some examples, the conductive layer grows on a carbon face of the substrate.

Crystals grown on the carbon face generally have a better crystalline quality than comparable crystals grown on the silicon face. In addition, surface preparation of the carbon face is easier, less time consuming and more cost-effective than that of the silicon face. In prior art processes, the conductive layer/high doped substrate is commonly grown on the carbon face of a seed crystal. Subsequently, drift layers are grown on the silicon face of the high doped substrate, for example during CVD. The claimed method thus provides a manufacturing process where the better crystalline quality provided by growth on the carbon face may be additionally utilized in the production of epitaxial wafers.

Specifically, a manufacturing process where growth on the silicon face may be completely avoided.

In some examples, the method comprises repeating the method at least one time, the method further comprising re-using the excess substrate as the substrate in the growth container.

Reusing the substrate in a succeeding growth run/cycle provides a more time-effective and cost-effective process.

In a second aspect of the disclosure, there is provided a silicon carbide (SiC) epitaxial wafer comprising a substrate layer of monocrystalline SiC having a doping concentration of ≤5·10¹⁶ cm⁻³ and a conductive layer of monocrystalline SiC having a doping concentration of ≥1·10¹⁸ cm⁻³. The epitaxial wafer is produced by providing a source material of polycrystalline SiC in the growth container, providing a substrate of monocrystalline SiC in the growth container substantially parallel to the source material, the substrate having a doping concentration of ≤5·10¹⁶ cm⁻³, increasing the temperature in the growth container to a sublimation temperature of the source material, maintaining the temperature in the growth container until a grown conductive layer of monocrystalline SiC of ≥10 μm having a doping concentration of ≥1·10¹⁸ cm⁻³ has grown on the substrate, wherein the substrate and the grown conductive layer together define an epitaxial boule, cooling the epitaxial boule to room temperature, and slicing the epitaxial boule, through the substrate in a plane substantially parallel to the grown conductive layer, into an excess substrate and an epitaxial wafer comprising a substrate layer having the grown conductive layer grown thereon.

In some examples, the substrate layer of the epitaxial wafer, has a doping concentration of ≤1·10¹⁶ cm⁻³.

In some examples, the substrate layer of the epitaxial wafer, is of n-type doping.

In some examples, the substrate layer of the epitaxial wafer, is of p-type doping.

In some examples, the substrate layer of the epitaxial wafer is substantially free from basal plane dislocations.

The presence of BPDs is detrimental to devices produced on the epitaxial wafer, since they may cause bipolar device degradation.

In some examples, the substrate layer of the epitaxial wafer is substantially free from stacking faults.

In some examples, the conductive layer is grown on a carbon face of the substrate.

### BRIEF DESCRIPTION OF DRAWINGS

The invention is now described, by way of example, with reference to the accompanying drawings, in which:

FIG. 1 displays a system according to the present disclosure for growth of epitaxial wafers.

FIG. 2 displays a method according to the present disclosure.

FIGS. 3a-3c display various phases of producing an epitaxial wafer according to the present disclosure.

### DESCRIPTION OF EMBODIMENTS

In the following, a detailed description of a method for producing monocrystalline epitaxial wafers of silicon carbide, SiC, will be described by way of exemplary embodiments. It should be understood that these embodiments are only exemplary and that there are many other embodiments that may be practiced within in the scope of the present invention by a person skilled in the art with help of the teachings in the present disclosure. In the drawing figures, like reference numerals designate identical or corresponding elements throughout the several figures. It will be appreciated that these figures are for illustration purposes only and are not in any way restricting the scope of the disclosure. When reference is made to directions such as up or down, above or below, this should be understood as being during normal operation of the systems disclosed herein.

One objective of the present disclosure is to provide a novel method of producing high quality epitaxial wafers by growing a monocrystalline material with a high doping concentration on a monocrystalline material with a low doping concentration. This goes directly against what is commonly practiced today. The following disclosure is based on the insight that by providing a substrate with a low doping concentration which is essentially free of basal plane dislocations and essentially free of stacking faults, a high-quality epitaxial wafer may be produced according to the method of the present disclosure.

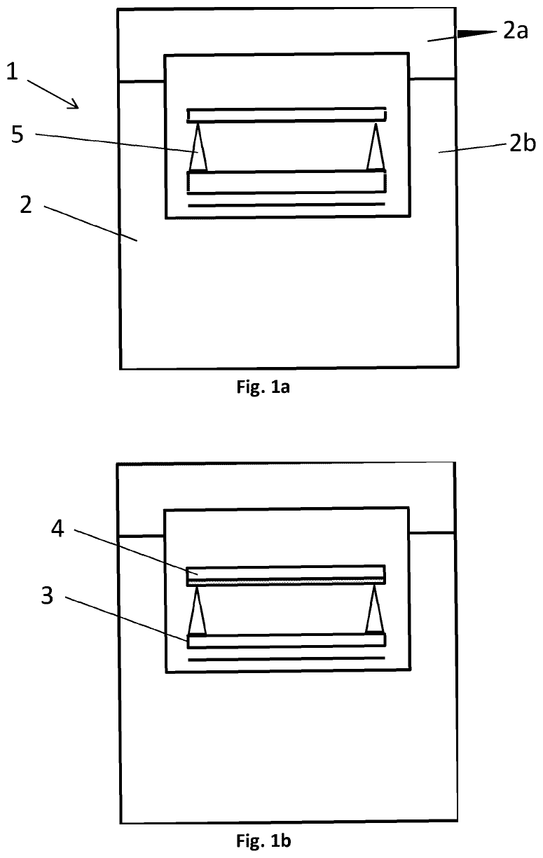

Firstly, a system 1 for growth of an epitaxial wafer will be described with reference to FIG. 1a and FIG. 1b.

In FIG. 1a and FIG. 1b there is displayed the growth system 1 for growth of an epitaxial wafer. Specifically, in the system 1 displayed in FIG. 1a and FIG. 1b, an epitaxial boule is grown. An epitaxial boule is, according to the present disclosure, a precursor to an epitaxial wafer. It is herein defined as a disc of monocrystalline SiC comprising two essentially parallel layers. The first layer is a substrate 4, which can be described as a precursor to a drift layer, having a greater thickness than a final drift layer. The second layer is a conductive layer 6.

Opposite to what is disclosed in prior art, the present disclosure comprises growing monocrystalline SiC having a high doping concentration on a substrate 4 of monocrystalline SiC having a low doping concentration. A high doping concentration should be understood as ≥1·10¹⁸ cm⁻³. A low doping concentration should be understood as ≤5·10¹⁶ cm⁻³, preferably ≤1·10¹⁶ cm⁻³. The doping concentration may for example be measured through secondary ion mass spectroscopy.

The growth system 1 is a physical vapor transport system. The growth system 1 is arranged for sublimation epitaxy, which refers to growth of epitaxial wafers or boules through sublimation. The growth system 1 may for example be arranged for the Fast Sublimation Growth Process (FSGP). The growth system 1 generally comprises an inner container 2, an insulating container and an outer container. The inner container 2 is, during operation arranged inside the insulating container. The insulating container is, during operation, arranged inside the outer container. The growth system 1 furthermore comprises a heating means. The heating means is arranged outside the outer container and is arranged to heat a cavity of the inner container 2. The heating means may be arranged for induction heating, for example in the form of an induction coil. The heating means may be arranged for resistive heating.

The heating means may be moveable in relation to the outer container. To this end, the growth system 1 may comprise a transport system arranged to move the heating means. The heating means may be movable in a vertical direction. The heating means may be moveable along a height of the outer container. This enables a temperature in the cavity of the inner container 2 to be controlled with high precision. This furthermore enables control of the speed of a temperature increase and temperature decrease. This furthermore enables control of a temperature drop inside the cavity of the inner container 2. The temperature drop is the difference in temperature between two positions in the cavity of the inner container 2 where one position is vertically above the other during normal operation.

The temperature in the cavity of the inner container 2 may furthermore be controlled by altering the design of the inner container 2, insulation container and outer container. The design may relate to a wall thickness of each of the containers. The design may relate to a relative size between the containers.

The inner container 2 may comprise an upper part 2a and a bottom part 2b. The upper part 2a may be arranged on top of the bottom part 2b. The upper part 2a may be sealingly engaged to the bottom part 2b, for example by having a snug fit between the top part and bottom part 2b, or by providing a threading on the parts. An inside of the upper part 2a and an inside of the bottom part 2b may together define the cavity of the inner container 2. The inner container 2 may be cylindrical. The inner container 2 may be formed by high-density graphite. The inner container 2 may be formed by a material suitable for withstanding high temperatures, such as above 1500° C. The inner container 2 may be formed by a material suitable for the type of heating means in each case. For example, if the growth system 1 comprises an induction heating means, the material of the inner container 2 should be suitable for heating by means of induction, which may be high-density graphite.

The insulation container may be cylindrical and may be formed by insulating graphite foam. The outer container may be cylindrical and may be formed by quartz. The insulation container is preferably provided for thermally insulating the inner container 2.

The growth system 1 may comprise pumps for evacuating the cavity of the inner container 2. The pumps may comprise inlets arranged in the cavity of the inner container 2 for pumping a gas into the cavity. The gas may be argon. The pumps may comprise outlets arranged in the cavity of the inner container 2 for pumping gas out from the cavity.

The pumps, and the associated inlets and outlets may furthermore be arranged for pumping a dopant gas into the cavity. The dopant gas may be nitrogen gas. The dopant gas may be for increasing a doping concentration during growth in the grown epitaxial layer. The system according to the disclosure provides a uniform distribution of dopant gas in the inner container 2, which may for example improve properties such as doping homogeneity.

The growth system 1 may comprise a carbon getter arranged to keep a stable and suitable Si/C stoichiometry during growth. The carbon getter may be arranged in the cavity of the inner container 2. The growth system 1 may comprise a plurality of carbon getters.

In the cavity of the inner container 2, during the process of growing the conductive layer 6, there is provided a source material 3 and the substrate 4. The substrate 4 may be arranged above the source material 3 in the cavity of the inner container 2. The substrate 4 may be arranged below the source material 3 in the cavity of the inner container 2.

The source material 3 is a monolithic, polycrystalline SiC source material 3. The source material 3 may have a columnar micro-grain structure. The grain size of the source material 3 may be between 1-250 μm. The grain size of the source material 3 may be between 1-100 μm. The microstructure may be a cubic microstructure. The source material 3 may be of n-type doping. The source material 3 may be of p-type doping.

The substrate 4 is a monolithic, monocrystalline SiC substrate. The crystalline structure of the substrate 4 may be of 4H polytype, 6H polytype, 15R polytype, 3C polytype or another suitable polytype. The substrate 4 has a low doping concentration of ≤5·10¹⁶ cm⁻³, preferably ≤1·10¹⁶ cm⁻³. This means that a difference between the concentration of electron donors and electron acceptors is below ≤5·10¹⁶ cm⁻³, preferably ≤1·10¹⁶ cm⁻³. The substrate 4 may be of n-type doping. The substrate 4 may be produced by sublimation growth. The substrate 4 may be produced by a separate process performed in the growth system 1 according to the present disclosure.

The substrate 4 is essentially free of stacking faults. Preferably, the substrate 4 is completely free of stacking faults. Stacking faults are planar defects in the microstructure resulting from lattice stresses, referred to as a higher stacking fault energy.

The substrate 4 is essentially free of basal plane dislocations. Preferably, the substrate 4 is completely free of basal plane dislocations (BPD). BPDs are microstructural defects in the material which may appear during growth of the substrate 4 or during cooling of the substrate 4 after growth. The presence of BPDs is detrimental to the epitaxial wafer, since the defects may propagate from the substrate 4 to the grown layer during growth. The BPD concentration may be measured by counting the BPDs. The counting may be manual or computer aided. Counting is preferably performed after suitable surface preparation such as etching, and after suitable enlargement, for example by means of a light optical microscope or scanning electron microscope.

The SiC substrate 4 has a crystalline structure comprising alternating layers of carbon and silicon which provides that the substrate 4 comprise a carbon side, known as the carbon face or C-face, and a silicon side, known as the silicon face or the Si-face. The substrate 4 is preferably arranged in the cavity of the inner container 2 such that the C-face is arranged to face the source material 3. Thus, when the conductive layer 6 grows thereon, it will grow on the C-face.

The substrate 4 may be arranged on at least one support 5, preferably at least two supports 5 are used. By means of the support 5, the source material 3 and the substrate 4 are preferably arranged such that the distance between them is lesser than an average mean free path for vapor species sublimed from the source material 3. In one embodiment, the at least one support 5 has an upper and a bottom part 2b and the upper part 2a of the support 5 contacts an outer edge of the substrate 4. In one embodiment, the bottom part 2b of the support 5 rests on the source material 3. In one embodiment, the bottom part 2b rests on the bottom of the inner container 2. In an alternative embodiment, the at least one support has a distal and a proximal part, wherein the proximal part is fixedly arranged on an inside surface of the inner container 2 and the distal part extends horizontally towards a center of the inner container 2 and wherein the substrate 4 rests on the distal part. The supports 5 displayed in FIG. 1a and FIG. 1b are pyramidal supports 5 which provide that the contact area between the supports 5 and the substrate 4 is minimized.

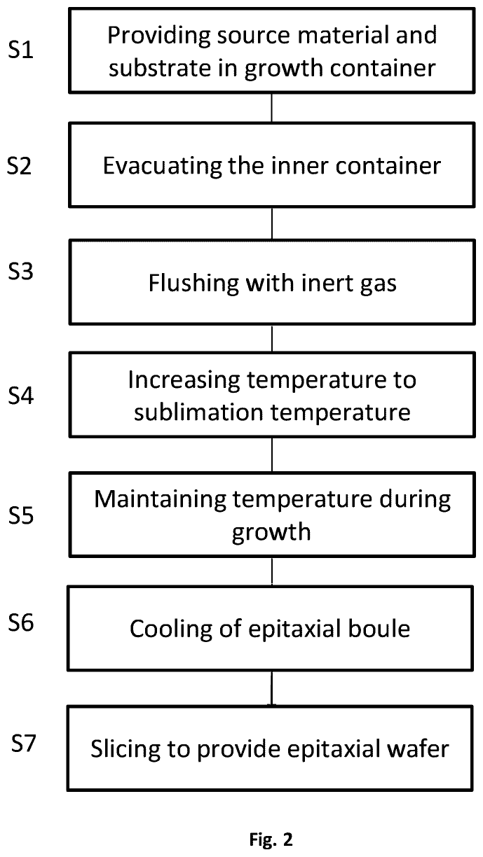

The method will now be described with reference to FIG. 2.

Step S1 of the method comprises providing the monolithic, polycrystalline source material 3 in the inner container 2 of the growth system 1 and providing the monolithic, monocrystalline substrate 4 above the source material 3 in the inner container 2. The substrate 4 is arranged at a distance of 0.5-2 mm above the source material 3, preferably at a distance of 0.7-1.3 mm above the source material 3, more preferably at a distance of 1 mm above the source material 3. This arrangement is displayed in FIG. 1a.

Step S2 of the method comprises evacuating the inner container 2 to provide a clean environment for growth. The inner container 2 may be evacuated to a pressure of 1 mbar, preferably ≤1 mbar, even more preferably ≤0.1 mbar.

Step S3 of the method comprises flushing the inner container 2 with an inert gas such as argon gas. Flushing the inner container 2 with inert gas has the purpose of ensuring a clean environment for growth, wherein the inert gas may flush out residuals of air. The inert gas furthermore has the purpose of inhibiting sublimation of unwanted gas species, which will be described more in detail below with reference to step S4. In one exemplary embodiment the inert gas is introduced into the chamber until the pressure reaches the range of 1 mbar to 10 mbar. In another exemplary embodiment the inert gas is introduced until the pressure has reached the range of 150 mbar to 950 mbar, preferably 700 mbar.

In step S4 the temperature in the inner container 2 is raised by means of the heating means to the sublimation temperature of the source material 3. A theoretical temperature at which sublimation of the substrate 4 starts may be ≥1500° C. During the raising step S4, the temperature in the inner container 2 may be raised to a sublimation temperature between 1650-2050° C. The temperature may for example be raised to a sublimation temperature of 1800° C., 1950° C., 1975° C., 2050° C. or another suitable sublimation temperature.

The inert gas in the inner container 2, introduced during step S3, has the effect of inhibiting sublimation of gas species sublimed at lower temperatures (below sublimation temperature) and thus preventing growth of such gas species on the substrate 4 during the step S4 of raising the temperature. As such, a controlled sublimation from the substrate 4 may be achieved by controlling the pressure in the inner container 2. In one embodiment, the pressure during the raising step S4 may be constant in a range of 1 mbar to 10 mbar. In one embodiment, the pressure during the raising step S4 may be reduced at a pumping rate of, e.g., 1 mbar/min to 10 mbar/min preferably 5 mbar/min until a pressure in the range of 0.01 mbar to 10 mbar, preferably in the range of 0.1 mbar to 10 mbar, more preferably a pressure in the range of 0.1 mbar to 5 mbar has been reached.

In step S5 the temperature in the inner container 2 is maintained. During step S5, the conductive layer 6 starts to grow on the substrate 4. The desired growth rate may be in the interval from 1 μm/h to 1 mm/h. Preferably the growth rate is kept between 10 μm/h to 500 μm/h. What growth rate that is desired depends on a balancing of productivity and quality. In one embodiment the sublimation temperature is kept at 1950° C., giving a growth rate of approximately 90 μm/h with the above-described setting. The person skilled in the art knows at which temperatures a desired growth rate is obtained. The temperature is maintained until the conductive layer 6 of a desired thickness has grown on the substrate 4. The desired thickness of the conductive layer 6 may be ≥5 μm. The desired thickness of the conductive layer 6 may be ≥10 μm. The desired thickness of the conductive layer 6 may depend on the intended use of the epitaxial wafer.

In step S6 the heating element is turned off and the substrate 4 is allowed to cool to room temperature. The substrate 4 is preferably cooled inside the inner container 2. During step S6 the inner container 2 may be refilled with inert gas to reach atmospheric pressure. The inert gas may be argon.

During steps S1-S6, the epitaxial boule is produced. The epitaxial boule comprises the substrate 4 and the thereon grown conductive layer 6. This is displayed in FIG. 1b.

The conductive layer 6 grown during the steps S1-S6 has a doping homogeneity of ≤15%, preferably ≤10%, more preferably ≤5%, most preferably ≤2%. The doping homogeneity is determined by comparing measured values of the doping concentration in different areas of the conductive layer, preferably between areas with the highest and the lowest doping concentration.

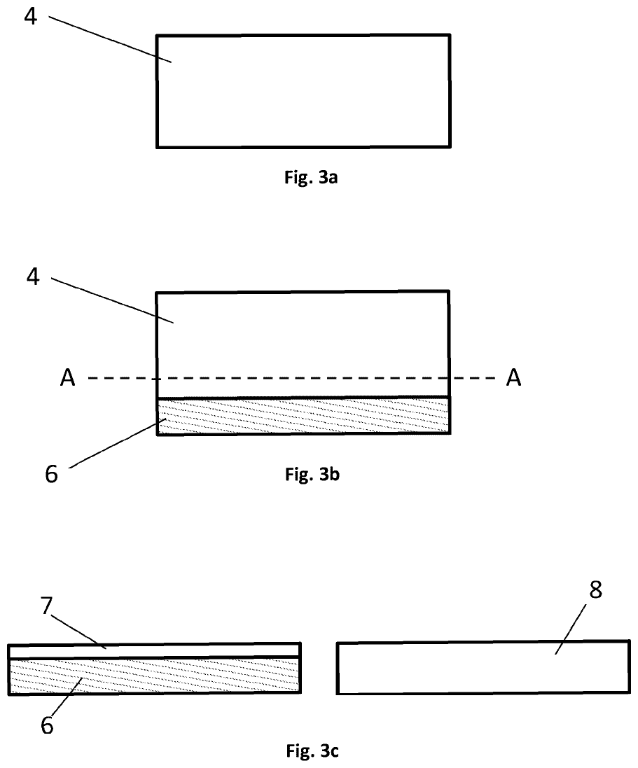

In step S7, the epitaxial boule is sliced through the substrate 4. The epitaxial boule is preferably sliced through the substrate 4 in a plane A-A substantially parallel to the grown conductive layer 6. The plane A-A can be seen in FIG. 3b. By means of the slicing, the epitaxial boule is divided into two parts. A first part is the epitaxial wafer comprising the conductive layer 6 and a substrate layer defining a drift layer 7. A second part is in the form of an excess substrate 8. A thickness of the drift layer 7 depends on the intended use of the epitaxial wafer. The thickness may for example depend on what voltage class the device produced from the epitaxial layer will be used in. The epitaxial boule may be sliced such that a drift layer 7 having a thickness of approximately 10 μm for each 1000 V is achieved.

In one example the drift layer 7 is 5 μm and is suitable for use in devices in the voltage class 600 V. In another example the drift layer 7 is 10 μm and is suitable for use in devices in the voltage class 1000 V. In another example the drift layer 7 is 10 μm and is suitable for use in devices in the voltage class 1200 V. These exemplary epitaxial wafers may for example be used in Schottky Barrier Diodes.

In one example the drift layer 7 is 16 μm and is suitable for use in devices in the voltage class 1700 V. In one example the drift layer 7 is 30 μm and is suitable for use in devices in the voltage class 3300 V. In one example the drift layer 7 is 60 μm and is suitable for use in devices in the voltage class 6500 V. These exemplary epitaxial wafers may for example be used in Metal Oxide Semiconductor Field Effect Transistor or Junction Barrier Schottky Diodes.

The slicing may be performed by a laser separation process, or a laser lift-off process. A laser separation process may for example comprise irradiating the epitaxial boule with laser at a given depth corresponding to the desired thickness of the layer to be removed. The irradiation may affect the bond between a carbon crystallographic layer and a silicon crystallographic layer, such as they may be detached from each other. The slicing may alternatively be performed by means of a wire saw or another separation process. Slicing may also be referred to as splitting.

The method may furthermore comprise post processing of the epitaxial wafer, for example in the form of stepwise surface and edge grinding, chemical mechanical polishing or wafer cleaning.

The method according to the present disclosure furthermore comprises repeating the method at least one time. When repeating the step S1 of the method, the excess substrate 8 produced during slicing in a previous run is provided as a substrate 4 in step S1.

In one example, when the substrate 4 is used a first time it has a thickness of 1400 μm. The conductive layer 6 grows thereon until the conductive layer 6 has a thickness of 350 μm. The epitaxial boule thus has a total thickness of 1750 μm. During slicing, the epitaxial boule is divided into the epitaxial wafer, comprising the 350 μm thick conductive layer 6 and the drift layer 7 having a thickness of 10 μm, and the excess substrate 8. The excess substrate 8 would theoretically have a thickness of 1390 μm, however, additional material is removed during slicing, why the excess substrate 8 in this example has a thickness of 1240 μm. The 1240 μm thick excess substrate 8 can thereafter be used as the substrate 4 in the next run during repeating of the method. This can be repeated until the substrate 4 is completely consumed. How many times the substrate 4 can be reused is dependent on the original thickness of the substrate 4.

FIGS. 3a-3c schematically display the substrate 4 and the conductive layer 6 in various phases of the process of manufacturing a SiC epitaxial wafer. In FIG. 3a only the substrate 4 is displayed, before the growth of the conductive layer 6. FIG. 3a represents the substrate 4 when it is provided (S1) in the inner container 2 of the growth system 1. FIG. 3b displays the substrate 4 when the conductive layer 6 has grown thereon (S6). The substrate 4 and conductive layer 6 in FIG. 3b may thereby be seen as displaying the epitaxial boule. The line A-A, as mentioned above, represents a plane essentially parallel to the grown conductive layer 6. The plane A-A can be seen as being perpendicular to a growth direction of the grown conductive layer 6. FIG. 3c displays the epitaxial wafer comprising the conductive layer 6 and the drift layer 7, and the excess substrate 8 after the step of slicing (S7) through a plane represented by the line A-A. The relative thickness between the substrate 4 and the conductive layer 6 in the figures should not be seen as limiting to the scope of the disclosure. The relative thickness between the excess substrate 8 and the epitaxial wafer in the figures should not be seen as limiting to the scope of the disclosure.

Preferred embodiments of SiC epitaxial wafers, and a method and system for production thereof, have been disclosed above. However, a person skilled in the art realizes that this can be varied within the scope of the appended claims without departing from the inventive idea.

All the described alternative embodiments above or parts of an embodiment can be freely combined or employed separately from each other without departing from the inventive idea as long as the combination is not contradictory.

1-13. (canceled)

14. A method for producing silicon carbide, SiC, epitaxial wafers in a wafer growth system comprising:
an outer container,
an insulating container, arranged inside the outer container,
a growth container, arranged inside the insulating container, and
a heating arrangement arranged outside the outer container to heat an inside of the growth container,
the method comprising:
providing a source material of polycrystalline SiC in the growth container,
providing a substrate of monocrystalline SiC in the growth container substantially parallel to the source material, the substrate having a doping concentration of ≤5·10¹⁶ cm⁻³,
increasing the temperature in the growth container to a sublimation temperature of the source material,
maintaining the temperature in the growth container until a conductive layer of monocrystalline SiC having a thickness of ≥10 μm and having a doping concentration of ≥1·10¹⁸ cm⁻³ has grown on the substrate, wherein the substrate and the grown conductive layer together define an epitaxial boule,
cooling the epitaxial boule to room temperature, and
slicing the epitaxial boule, through the substrate in a plane substantially parallel to the grown conductive layer, into an excess substrate and an epitaxial wafer comprising a substrate layer having the grown conductive layer thereon.

15. The method according to claim wherein the substrate has a doping concentration of ≤1·10¹⁶ cm⁻³.

16. The method according to claim 14, wherein the substrate has a thickness of ≥100 μm.

17. The method according to claim wherein the substrate is substantially free from basal plane dislocations.

18. The method according to claim 14, wherein the substrate is substantially free from stacking faults.

19. The method according to claim 14, wherein the conductive layer grows on a carbon face of the substrate.

20. The method according to claim 14, further comprising repeating the method at least one time, the method further comprising:
re-using the excess substrate as the substrate in the growth container.

21. A silicon carbide (SiC) epitaxial wafer comprising:
a substrate layer of monocrystalline SiC having a doping concentration of ≤5·10¹⁶ cm⁻³ and,
a conductive layer of monocrystalline SiC having a doping concentration of ≥1·10¹⁸ cm⁻³, wherein the epitaxial wafer is produced by:
providing a source material of polycrystalline SiC in the growth container,
providing a substrate of monocrystalline SiC in the growth container substantially parallel to the source material, the substrate having a doping concentration of ≤5·10¹⁶ cm⁻³,
increasing the temperature in the growth container to a sublimation temperature of the source material,
maintaining the temperature in the growth container until a grown conductive layer of monocrystalline SiC of ≥10 μm having a doping concentration of ≥1·10¹⁸ cm⁻³ has grown on the substrate, wherein the substrate and the grown conductive layer together define an epitaxial boule,
cooling the epitaxial boule to room temperature, and
slicing the epitaxial boule, through the substrate in a plane substantially parallel to the grown conductive layer, into an excess substrate and an epitaxial wafer comprising a substrate layer having the grown conductive layer grown thereon.

22. The epitaxial wafer according to claim 21, wherein the substrate layer of the epitaxial wafer, has a doping concentration of ≤1·10¹⁶ cm⁻³.

23. The epitaxial wafer according to claim 21, wherein the substrate layer of the epitaxial wafer is substantially free from basal plane dislocations.

24. The epitaxial wafer according to claim 21, wherein the substrate layer of the epitaxial wafer is substantially free from stacking faults.

25. The epitaxial wafer according to claim 21, wherein the conductive layer is grown on a carbon face of the substrate.

26. The epitaxial wafer according to claim 21, wherein the conductive layer displays a doping homogeneity of ≤15%.

27. The epitaxial wafer according to claim 26, wherein the conductive layer displays a doping homogeneity of ≤10%.

28. The epitaxial wafer according to claim 26, wherein the conductive layer displays a doping homogeneity of ≤5%.

29. The epitaxial wafer according to claim 26, wherein the conductive layer (6) displays a doping homogeneity of ≤2%.
